(19) United States
(12) Patent Application Publication
(10) Pub. No.: US 2023/0411348 A1
(43) Pub. Date: Dec. 21, 2023

(54) CHIP-FIRST LAYERED PACKAGING ARCHITECTURE

(71) Applicant: Intel Corporation, Santa Clara, CA (US)

(72) Inventors: Carlton Hanna, Santa Jose, CA (US); Bernd Waidhas, Pettendorf (DE); Thomas Wagner, Regelsbach (DE)

(73) Assignee: Intel Corporation, Santa Clara, CA (US)

(21) Appl. No.: 17/842,093

(22) Filed: Jun. 16, 2022

(51) Int. Cl. H01L 25/065; H01L 23/00; H01L 21/56; H01L 21/48; H01L 23/29; H01L 23/538; H01L 23/48

(52) U.S. Cl. CPC H01L 25/0652; H01L 24/73; H01L 24/16; H01L 24/08; H01L 24/09; H01L 21/565; H01L 21/486; H01L 23/293; H01L 23/5381; H01L 23/5385; H01L 23/481; H01L 24/05; H01L 2924/37001; H01L 2924/3512; H01L 2924/3841; H01L 2924/381; H01L 2924/1434; H01L 2924/1431; H01L 24/13; H01L 2224/13147; H01L 23/49816

(57) ABSTRACT

Embodiments of a microelectronic assembly comprise a first integrated circuit (IC) die having first bond-pads on a first surface; an organic dielectric material in contact with the first surface; second bond-pads on a second surface of the organic dielectric material opposite to the first surface; through-dielectric vias (TDVs) in the dielectric material between the first bond-pads and the second bond-pads, wherein the TDVs are in direct contact with the first bond-pads and the second bond-pads; a second IC die embedded in the organic dielectric material and coupled to the first bond-pads by first interconnects; and a package substrate coupled to the second bond-pads by second interconnects.

### TECHNICAL FIELD

The present disclosure relates to techniques, methods, and apparatus directed to a chip-first layered packaging architecture.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIG. 2 is a schematic cross-sectional view of another example microelectronic assembly according to some embodiments of the present disclosure.

FIG. 3 is a schematic cross-sectional view of a portion of an example microelectronic assembly according to some embodiments of the present disclosure.

FIG. 4 is a schematic cross-sectional view of a portion of another example microelectronic assembly according to some embodiments of the present disclosure.

FIG. 5 is a schematic cross-sectional view of a portion of yet another example microelectronic assembly according to some embodiments of the present disclosure.

FIG. 6 is a schematic cross-sectional view of a portion of yet another example microelectronic assembly according to some embodiments of the present disclosure.

FIGS. 7A-7G are schematic cross-sectional views of various stages of manufacture of an example microelectronic assembly according to some embodiments of the present disclosure.

FIGS. 8A-8G are schematic cross-sectional views of various stages of manufacture of another example microelectronic assembly according to some embodiments of the present disclosure.

FIG. 9 is a cross-sectional view of a device package that includes one or more microelectronic assemblies in accordance with any of the embodiments disclosed herein.

FIG. 10 is a cross-sectional side view of a device assembly that includes one or more microelectronic assemblies in accordance with any of the embodiments disclosed herein.

FIG. 11 is a block diagram of an example computing device that includes one or more microelectronic assemblies in accordance with any of the embodiments disclosed herein.

### DETAILED DESCRIPTION

Overview

For purposes of illustrating IC packages described herein, it is important to understand phenomena that may come into play during assembly and packaging of IC dies. The following foundational information may be viewed as a basis from which the present disclosure may be properly explained. Such information is offered for purposes of explanation only and, accordingly, should not be construed in any way to limit the broad scope of the present disclosure and its potential applications.

Advanced node semiconductor solutions are moving in a direction of IC die disaggregation with small IC dies (also called “chiplets”) combined to form larger system solutions. This is done for both cost efficiency and mixing process node types (e.g., digital, radio frequency (RF), power delivery, memory, etc.). Advanced package technology options are being introduced with a variety of options to aggregate such IC dies. The package may compromise on power delivery, process yield, proximity of IC dies, interconnect density and a variety of different options to enable different IC dies made using different silicon processing nodes to be packaged into a single component. In one example, this solution allows vertical layers (stacking) of IC dies with different die sizes and functions, while also maintaining optimal power delivery.

In addition, many computing schemes such as artificial intelligence, machine learning and other emerging applications require more computing horsepower with higher performance, extremely low latency, and smaller form factors than traditional computing applications. Such demands foster the development of a 2.5-dimensional (2.5D) or 3-dimensional (3D) multi-chip package technology. Conventionally, 2.5-D package architecture is achieved by utilizing an IC die or silicon interposer as a bridge die to couple two adjacent IC dies on top of the bridge die, for example, to achieve higher aggregated data bandwidth, low latency, less interconnect loss, and hence less power consumption. The two IC dies being coupled may comprise circuits of different functionalities such as application specific integrated circuits (ASIC), RF circuits, and memory circuits. The interposer typically has through-substrate vias (TSV) (also referred to as through-silicon vias in cases where the substrate is silicon and the vias do not extend through the entire thickness of the substrate) to enable electrical connectivity of the top IC dies with a package substrate underneath.

Existing interposer technology utilizes molded interposers that are separate and independent components from the IC dies to which they are coupled. Such molded interposers are typically fabricated on a carrier, and known good dies (KGDs) are attached at the very end of the fabrication process to redistribution layers (RDLs) on the top of the interposer using solder-based interconnects or copper bumps with solder caps. Then underfill is dispensed, the assembly is overmolded and ground down. The carrier is removed and the bottom RDL and solder bumps for attaching to a package substrate are added to the interposer on a surface opposite to the attached KGDs. Thus, there are two sets of solder-based interconnects when an interposer is used: one set couples the KGDs to the interposer, and another set on the opposite side of the interposer couples the interposer to a package substrate.

Solder-based interconnects are not particularly desirable for power delivery or signal integrity as they have several reliability issues. For example, solder interconnects are known to form voids from electromigration at high current densities. They have intrinsic delay in signal propagation due to high current-resistance (IR) drop. They crack from thermo-mechanical fatigue due to co-efficient of thermal expansion (CTE) mismatch between the components they couple. Failures can occur at intermetallic boundaries comprising solder. In addition, solder-based interconnects typically utilize RDLs to translate bump pitch and prevent stress failures, but which negatively impact cost and yield. Thus, reducing the number of solder-based interconnects in any electronic assembly can improve reliability.

Accordingly, embodiments of the present disclosure provide a microelectronic assembly comprising: a first IC die having first bond-pads on a first surface; an organic dielectric material in contact with the first surface; second bond-pads on a second surface of the organic dielectric material opposite to the first surface; through-dielectric vias (TDVs) (also called through-mold vias (TMVs) in cases where the surrounding dielectric material is mold compound) in the dielectric material between the first bond-pads and the second bond-pads, wherein the TDVs are in direct contact with the first bond-pads and the second bond-pads; a second IC die embedded in the organic dielectric material and coupled to the first bond-pads by first interconnects; and a package substrate coupled to the second bond-pads by second interconnects.

Embodiments of the microelectronic assembly as disclosed herein comprise copper pillar structures that function as TDVs with different diameters contacted on the top die surface for improved power delivery and low loss signal connection. This may be achieved by a chip first advanced packaging technology and process that allows for multiple layers of disaggregated IC dies. Vertical die-to-die connections are through microbumps in some embodiments, and horizontal die-to-die connections are through one or more bridge dies. Embodiments of the microelectronic assembly as described herein allow for multiple layer disaggregation of IC dies with a less complex process than conventional interposer technology. Power delivery may also be improved with direct vias to top IC dies. Various embodiments of the microelectronic assembly as described herein may not be limited by reticle sizes (e.g., either in die fabrication operations or RDL operations), and can be applied to form large complex structures with multiple stacked layers of IC dies in a single package.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group Ill-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit board (PCBs) such insulating material comprises organic materials such as Ajinomoto Buildup Film (ABF™), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

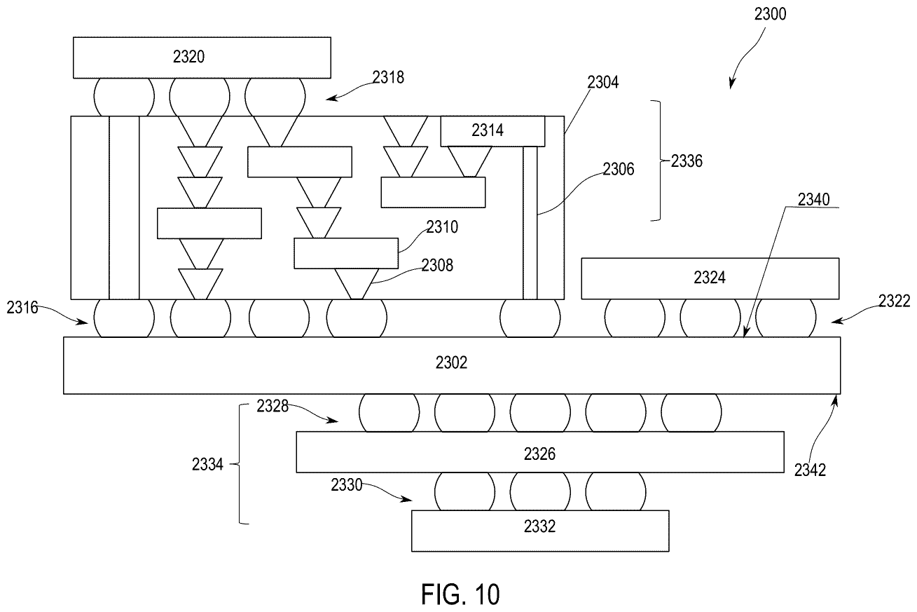

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### EXAMPLE EMBODIMENTS

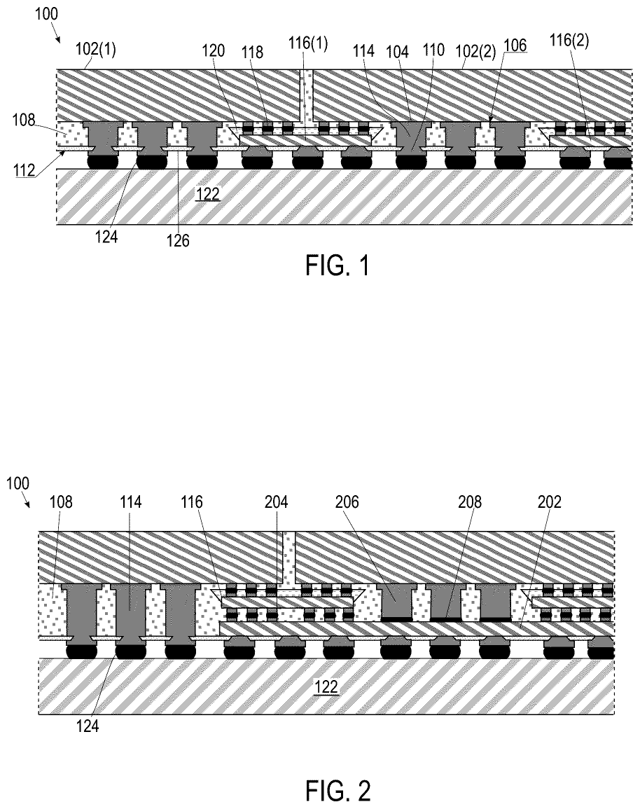

FIG. 1 is a schematic cross-sectional view of an example microelectronic assembly 100 according to some embodiments of the present disclosure. Microelectronic assembly 100 comprises, in the embodiment shown, one or more IC die 102 (e.g., 102(1), 102(2)) having bond-pads 104 on a surface 106. IC die 102 may be a KGD in various embodiments. In a general sense, the KGD is typically a semiconductor die with ICs that have passed various testing operations, such as wafer probe, burn-in, functional test, screening, etc., and are operating within design parameters. The KGDs are manufactured in wafer form, singulated, tested (before or after singulation) and screened before being used in microelectronic assembly 100. Microelectronic assembly 100 further comprises an organic dielectric material 108 in direct contact with surface 106. In various embodiments, organic dielectric material 108 comprises mold compound with or without fillers. Organic dielectric material 108 has bond-pads 110 on a second surface 112 opposite to surface 106.

In various embodiments, TDVs 114 in organic dielectric material 108 are in direct contact with bond-pads 104 and 110. Bond-pads 104 may comprise a first subset of bond-pads having a pitch of approximately 100 micrometers (or greater) and a second subset of bond-pads having a pitch of approximately 25 micrometers (or smaller). In general, bond-pads 104 in the first subset may be larger than bond-pads 104 in the second subset. TDVs 114 may be in direct contact with the first subset of bond-pads. One or more IC die 116 (e.g., 116(1), 116(2)) may be embedded in organic dielectric material 108 and coupled to the second subset of bond-pads 104 of IC die 102 by interconnects 118. In some embodiments, IC die 116 may comprise a bridge die without any active circuitry (e.g., transistors, diodes, etc.) therein. In such embodiments, IC die 116 may comprise merely a metallization stack over a semiconductor substrate, with conductive traces and vias in the metallization stack. In some other embodiments, IC die 116 may comprise memory circuitry or other types of circuitry that may function together with circuitry in IC die 102. In various embodiments, IC die 116 may comprise TSVs for vertical connectivity.

In various embodiments, interconnects 118 may be in direct contact with bond-pads 104. In some embodiments, interconnects 118 may comprise DTD interconnects as described in the previous subsection; particular examples include microbumps (e.g., solder-ball based bumps, copper bumps, etc.) and hybrid bonds (e.g., metal-metal bonds alongside oxide-oxide bonds). In embodiments where interconnects 118 comprise solder-based materials, an underfill material 120 may be disposed around interconnects 118 in organic dielectric material 108 between IC die 102 and IC die 116.

In various embodiments, IC die 116 may provide conductive pathways in a lateral direction (e.g., IC die 116 functioning as a bridge between IC dies 102(1) and 102(2)), and interconnects 118 and TDVs 114 may provide conductive pathways in a direction perpendicular to the lateral direction, for example, to supply power and ground connections from a package substrate 122. In some embodiments, TDVs 114 (not shown) may also be present between IC die 116 and bond-pads 110. Package substrate 122 may be coupled to bond-pads 110 by interconnects 124. Interconnects 124 may comprise DTPS interconnects as described in the previous subsection. In many embodiments, a solder resist material 126 may be present between organic dielectric material 108 and interconnects 124. In some embodiments, bond-pads 110 may be located between solder resist material 126 and interconnects 124. IC die 116 may be coupled to package substrate 122 through interconnects 124. In various embodiments, the conductive material of traces, vias, bond-pads, etc. in microelectronic assembly 100 may comprise copper.

FIG. 2 is a schematic cross-sectional view of another example microelectronic assembly 100 according to some embodiments of the present disclosure. In some embodiments, in addition to the elements as described in reference to FIG. 1, another IC die 202 may be embedded in organic dielectric material 108. IC die 202 may comprise active circuitry in some embodiments; in other embodiments, IC die 202 may not comprise active circuitry. IC die 116 may be coupled to IC die 202 by interconnects 204. Interconnects 204 may comprise DTD interconnects, including microbumps in some embodiments and hybrid bonds in others. In some embodiments, TDVs 206 may be present between IC die 202 and bond-pads 104 on surface 106. TDVs 206 may be coupled to IC die 202 by interconnects 208. In such embodiments, IC die 202 may comprise conductive pads on a surface opposite to package substrate 122, and interconnects 208 may be bonded with the conductive pads. In some embodiments (not shown), IC die 202 may comprise TSVs to enable electrical connectivity between package substrate 122 and IC die 116, for example.

In some embodiments TDVs (not shown) may also be present between IC die 202 and bond-pads 110. In such embodiments, the TDVs may be bonded to conductive pads on the side of IC die 202 proximate to package substrate 122. IC die 202 may be coupled to package substrate 122 through interconnects 124. Thus, a stack of IC dies (e.g., 116, 202) may be provided in organic dielectric material 108. Although the figure shows only two layers in the stack, any number of layers comprising one or more IC dies in each layer may be included in microelectronic assembly 100 within the broad scope of the embodiments.

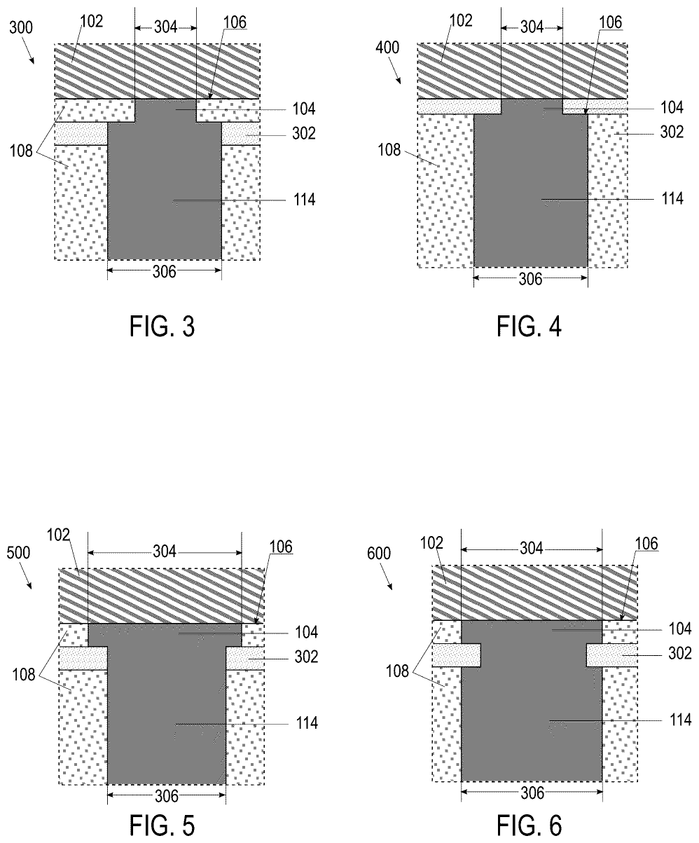

FIG. 3 is a schematic cross-sectional view of a portion 300 of microelectronic assembly 100 according to some embodiments of the present disclosure. In some embodiments, a polyimide layer 302 may be present in microelectronic assembly 100. In the embodiment shown, polyimide layer 302 is embedded in organic dielectric material 108 proximate to a region where bond-pads 104, which protrude from surface 106, are in direct contact with TDVs 114. Thus, a portion of organic dielectric material 108 in on one side of polyimide layer 302, and another portion of organic dielectric material 108 in on an opposing side of polyimide layer 302. Polyimide layer 302 may function as a stress buffer, permitting slight misalignments between bond-pad 104 and TDV 114. In some embodiments (as shown), bond-pad 104 may have a diameter 304 that is smaller than a diameter 306 of TDV 114. In such cases, a portion of TDV 114 may extend beyond bond-pad 104, and organic dielectric material 108 may act as a stress buffer in such structures, protecting the metallization stack of IC die 102 from stresses arising due to the intimate contact between different materials (e.g., IC die 102 and organic dielectric material 108) having different coefficients of thermal expansion and other material properties.

FIG. 4 is a schematic cross-sectional view of a portion 400 of microelectronic assembly 100 according to some embodiments of the present disclosure. In the embodiment shown in the figure, surface 106 of IC die 102 may include polyimide layer 302. Bond-pad 104 may be flush with the surface of polyimide layer 302. Organic dielectric material 108 may be in direct contact with polyimide layer 302.

FIG. 5 is a schematic cross-sectional view of a portion 500 of microelectronic assembly 100 according to some embodiments of the present disclosure. The embodiment shown in the figure is substantially identical to that in FIG. 3 except that diameter 304 of bond-pad 104 is larger than diameter 306 of TDV 114.

FIG. 6 is a schematic cross-sectional view of a portion 600 of microelectronic assembly 100 according to some embodiments of the present disclosure. The embodiment shown in the figure is substantially identical to that in FIG. 3 except that diameter 304 of bond-pad 104 is approximately equal to diameter 306 of TDV 114.

Various other configurations and types of IC dies 102, 116 and 202 not specifically described herein are included within the broad scope of the embodiments. In various embodiments, any of the features discussed with reference to any of FIGS. 1-6 herein may be combined with any other features to form a package with one or more IC dies as described herein, for example, to form a modified microelectronic assembly 100. Some such combinations are described above, but, in various embodiments, further combinations and modifications are possible.

Example Methods

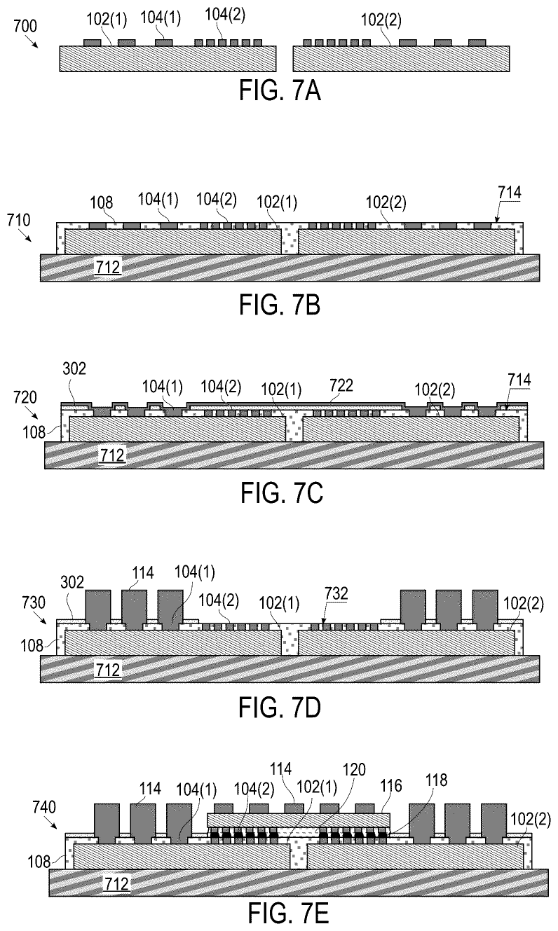

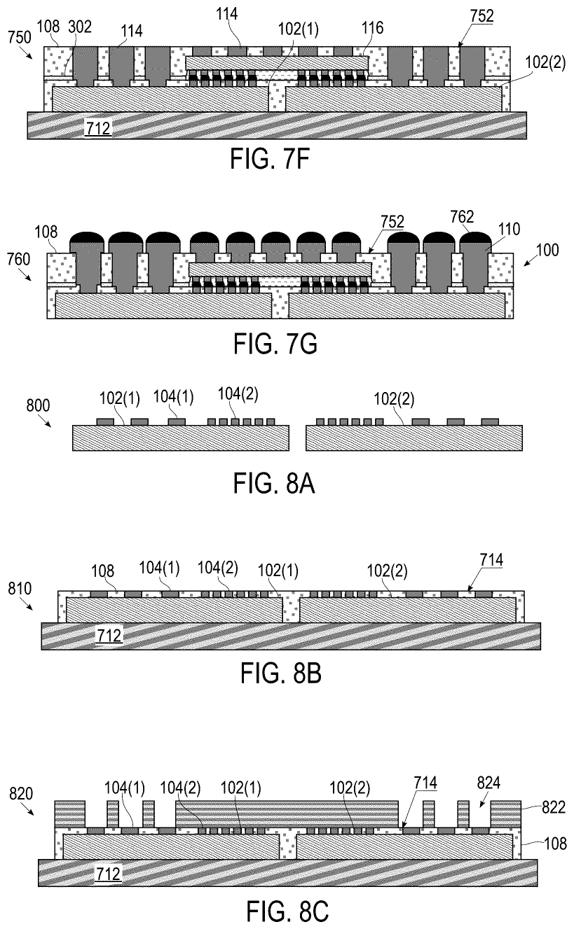

FIGS. 7A-7G are schematic cross-sectional views of various stages of manufacture of an example microelectronic assembly 100 according to some embodiments of the present disclosure. In various embodiments, a portion of microelectronic assembly 100 as described in the preceding figures, comprising all the elements as described with the exception of IC dies 102 and package substrate 122 may be considered as an interposer that is not separate from IC dies 102. A method of fabricating such an interposer may comprise the following operations as described herein.

FIG. 7A shows an assembly 700 comprising IC dies 102 having bond-pads 104. A first subset of bond-pads 104(1) may have a first pitch (e.g., greater than 100 micrometers) and a second subset of bond-pads 104(2) having a second pitch (e.g., less than 25 micrometers). In embodiments in which polyimide layer 302 is in direct contact with IC die 102 (not shown), IC die 102 may be prefabricated with polyimide layer 302 in a wafer-level process before being diced, tested and binned (e.g., categorized) as a KGD.

FIG. 7B shows an assembly 710 subsequent to attaching IC dies 102 on a carrier 712 and encapsulating with organic dielectric material 108. In many embodiments, a surface 714 of organic dielectric material 108 may be planarized such that surfaces of bond-pads 104 are made visible.

FIG. 7C shows an assembly 720 subsequent to depositing polyimide layer 302 on surface 714 of organic dielectric material 108 and patterning polyimide layer 302 appropriately. A seed layer 722, comprising copper in some embodiments, or under-bump metallization (UBM) in other embodiments, may be deposited over patterned polyimide layer 302.

FIG. 7D shows an assembly 730 subsequent to forming conductive pillars corresponding to TDVs 114 and removing polyimide layer 302 and seed layer 722 over second subset of bond-pads 104(2) to expose a surface 732. TDVs 114 may be formed by electroplating in some embodiments.

FIG. 7E shows an assembly 740 subsequent to attaching IC die 116 to second subset of bond-pads 104(2) by interconnects 118. In embodiments where interconnects are microbumps (e.g., solder balls or copper pillars), thermocompression bonding (TCB) and/or laser-assisted bonding (LAB) may be used for the attachment operation. Underfill material 120 may be dispensed between IC die 102 and IC die 116 around interconnects 118 and cured suitably, for example, using ultraviolet energy or heat. In embodiments where interconnects are hybrid bonds comprising metal-metal bonds and oxide-oxide bonds, a layer of silicon oxide may be applied over bond-pads 104(2), patterned and then plated with copper to form a suitable interface with IC die 116. In such embodiments, IC die 116 may also present a matching interface comprising copper pads in oxide. IC die 116 may be aligned on bond-pads 104(2) and subjected to thermocompression process as appropriate to form hybrid bonds. In some such embodiment, TDVs 114 may be formed after attaching IC die 116.

FIG. 7F shows an assembly 760 subsequent to encapsulating with additional organic dielectric material 108. TDVs may be formed on a side of IC die 116 opposite to IC die 102 prior to encapsulation. A surface 752 of organic dielectric material 108 may be planarized such that surfaces of TDVs 114 are visible.

FIG. 7G shows an assembly 770 subsequent to forming bond-pads 110 and bumps 762 (e.g., of interconnects 124) thereon. Carrier 712 may be released and assembly 770 may be inverted and bonded to package substrate 122 (not shown).

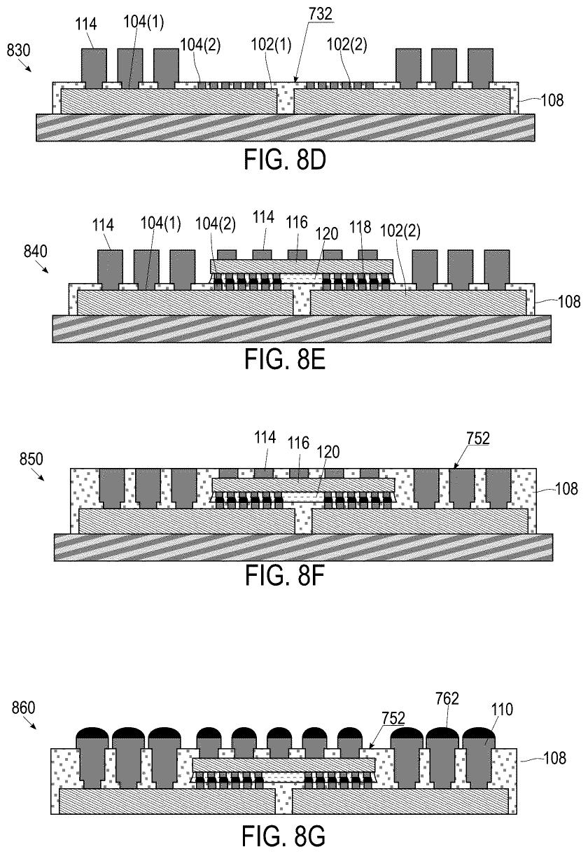

FIGS. 8A-8G are schematic cross-sectional views of various stages of manufacture of an example microelectronic assembly 100 according to some embodiments of the present disclosure. FIG. 8A shows an assembly 800 comprising IC dies 102 having bond-pads 104. A first subset of bond-pads 104(1) may have a first pitch (e.g., greater than 100 micrometers) and a second subset of bond-pads 104(2) having a second pitch (e.g., less than 25 micrometers).

FIG. 8B shows an assembly 810 subsequent to attaching IC dies 102 on carrier 712 and encapsulating with organic dielectric material 108. In many embodiments, a surface 714 of organic dielectric material 108 may be planarized such that surfaces of bond-pads 104 are made visible.

FIG. 8C shows an assembly 820 subsequent to depositing photoresist material 822 on surface 714 and patterning it suitably to create vias 824 therein corresponding to TDVs 114.

FIG. 8D shows an assembly 830 subsequent to forming conductive pillars corresponding to TDVs 114 and removing photoresist material 822 over second subset of bond-pads 104(2) to expose surface 732. TDVs 114 may be formed by electroplating in some embodiments.

FIG. 8E shows an assembly 840 subsequent to attaching IC die 116 to second subset of bond-pads 104(2) by interconnects 118 and forming additional TDVs 114 over IC die 116. In embodiments where interconnects are microbumps (e.g., solder balls or copper pillars), TCB and/or LAB may be used for the attachment operation. Underfill material 120 may be dispensed between IC die 102 and IC die 116 around interconnects 118 and cured suitably, for example, using ultraviolet energy or heat. In embodiments where interconnects are hybrid bonds comprising metal-metal bonds and oxide-oxide bonds, a layer of silicon oxide may be applied over bond-pads 104(2), patterned and then plated with copper to form a suitable interface with IC die 116. In such embodiments, IC die 116 may also present a matching interface comprising copper pads in oxide. IC die 116 may be aligned on bond-pads 104(2) and subjected to thermocompression process as appropriate to form hybrid bonds. In some such embodiment, TDVs 114 may be formed after attaching IC die 116.

FIG. 8F shows an assembly 850 subsequent to encapsulating with additional organic dielectric material 108. Surface 752 of organic dielectric material 108 may be planarized such that surfaces of TDVs 114 are visible.

FIG. 8G shows an assembly 860 subsequent to forming bond-pads 110 and bumps 762 (e.g., of interconnects 124) thereon. Carrier 712 may be released and assembly 860 may be inverted and bonded to package substrate 122 (not shown).

Although FIGS. 7-8 illustrates various operations performed in a particular order, this is simply illustrative, and the operations discussed herein may be reordered and/or repeated as suitable. Further, additional processes which are not illustrated may also be performed without departing from the scope of the present disclosure. Also, various ones of the operations discussed herein with respect to FIGS. 7-8 may be modified in accordance with the present disclosure to fabricate others of microelectronic package 100 disclosed herein. Although the operations are illustrated in FIGS. 7-8 once each, the operations may be repeated as often as desired. For example, one or more operations may be performed in parallel to manufacture multiple microelectronic packages substantially simultaneously. In another example, the operations may be performed in a different order to reflect the structure of a particular microelectronic package 100 as described herein.

Furthermore, the operations illustrated in FIGS. 7-8 may be combined or may include more details than described. Still further, the operations as described may further include other manufacturing operations related to fabrication of other components of the microelectronic assemblies described herein, or any devices that may include the microelectronic assemblies as described herein. For example, the operations may include various cleaning operations, surface planarization operations (e.g., using chemical mechanical polishing (CMP)), operations for surface roughening, operations to include barrier and/or adhesion layers as desired, and/or operations (e.g., solder reflow, epoxy curing, etc.) for incorporating microelectronic packages as described herein in, or with, an IC component, a computing device, or any desired structure or device.

Example Devices and Components

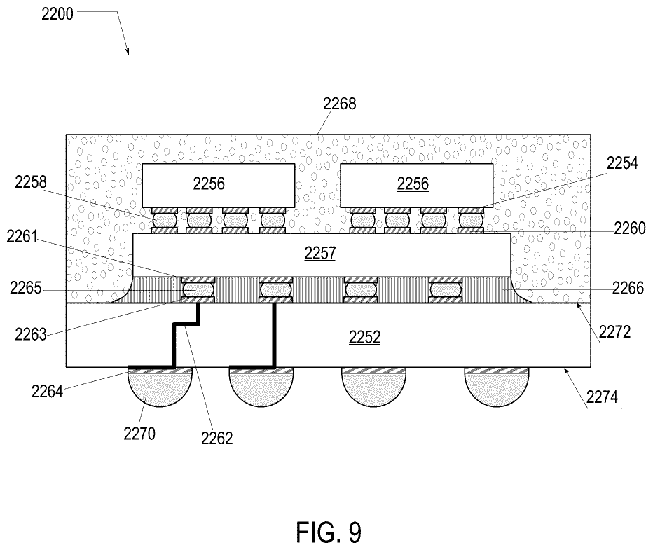

The packages disclosed herein, e.g., any of the embodiments shown in FIGS. 1-8 or any further embodiments described herein, may be included in any suitable electronic component. FIGS. 9-11 illustrate various examples of packages, assemblies, and devices that may be used with or include any of the IC packages as disclosed herein.

FIG. 9 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. In some embodiments, first-level interconnects 2258 and conductive contacts 2260 may be absent as described previously. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 10.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 10 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 9.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 9. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group Ill-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as RF devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

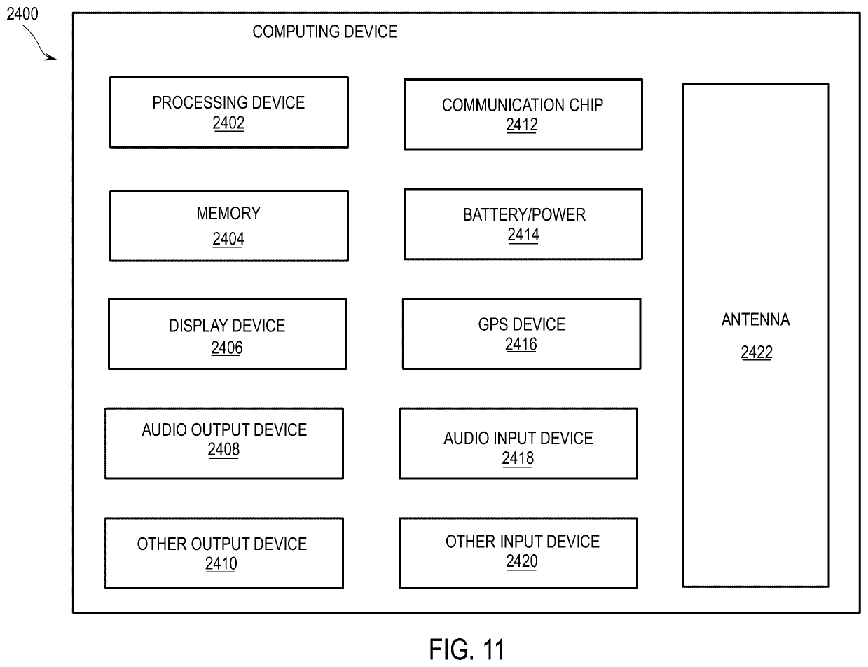

FIG. 11 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 9). In yet another example, any one or more of the components of computing device 2400 may include an IC device assembly 2300 (e.g., as shown in FIG. 10).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-chip (SOC) die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, memory 2404 may include memory that shares a die with processing device 2402. This memory may be used as cache-memory and may include embedded-DRAM (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 provides a microelectronic assembly (e.g., 100), comprising (e.g., FIGS. 1, 2): a first integrated circuit (IC) die (e.g., 102) having first bond-pads (e.g., 104) on a first surface (e.g., 106); an organic dielectric material (e.g., 108) in contact with the first surface; second bond-pads (e.g., 110) on a second surface (e.g., 112) of the organic dielectric material opposite to the first surface; through-dielectric vias (TDVs) (e.g., 114) in the organic dielectric material between the first bond-pads and the second bond-pads, in which the TDVs are in direct contact with the first bond-pads and the second bond-pads; a second IC die (e.g., 116) embedded in the organic dielectric material and coupled to the first bond-pads by first interconnects (e.g., 118); and a package substrate (e.g., 122) coupled to the second bond-pads by second interconnects (e.g., 124).

Example 2 provides the microelectronic assembly of example 1, in which: the first bond-pads comprise a first subset of bond-pads and a second subset of bond-pads, the TDVs are in direct contact with the first subset of bond-pads, and the interconnects between the first IC die and the second IC die are in direct contact with the second subset of bond-pads.

Example 3 provides the microelectronic assembly of example 2, in which: the bond-pads in the first subset are spaced apart according to a first pitch, the bond-pads in the second subset are spaced apart according to a second pitch, and the first pitch is larger than the second pitch.

Example 4 provides the microelectronic assembly of example 3, in which the first pitch is approximately 100 micrometers, and the second pitch is approximately 25 micrometers.

Example 5 provides the microelectronic assembly of example 3, in which the first pitch is not less than 100 micrometers and the second pitch is not greater than 25 micrometers.

Example 6 provides the microelectronic assembly of example 3, in which the first pitch is between 25 micrometers and 100 micrometers and the second pitch is not greater than 25 micrometers.

Example 7 provides the microelectronic assembly of example 3, in which the first pitch is not less than 100 micrometers and the second pitch is between 25 micrometers and 100 micrometers.

Example 8 provides the microelectronic assembly of any one of examples 2-7, in which: the bond-pads in the first subset are larger than the bond-pads in the second subset.

Example 9 provides the microelectronic assembly of any one of examples 1-8, in which the first interconnects comprise microbumps including solder.

Example 10 provides the microelectronic assembly of any one of examples 1-9, in which the first interconnects comprise metal-metal bonds and oxide-oxide bonds.

Example 11 provides the microelectronic assembly of any one of examples 1-10, in which the second IC die provides conductive pathways in a lateral direction and the first interconnects and the TDVs provide conductive pathways in a vertical direction perpendicular to the lateral direction.

Example 12 provides the microelectronic assembly of any one of examples 1-11, further comprising an underfill material (e.g., 120) in the organic dielectric material between the first IC die and the second IC die.

Example 13 provides the microelectronic assembly of any one of examples 1-12, further comprising a solder resist material (e.g., 126) between the organic dielectric material and the second interconnects.

Example 14 provides the microelectronic assembly of example 13, in which the second bond-pads are between the solder resist material and the second interconnects.

Example 15 provides the microelectronic assembly of any one of examples 1-14, in which the second IC die is coupled to the package substrate through the second interconnects.

Example 16 provides the microelectronic assembly of any one of examples 1-15, further comprising a plurality of the first IC dies, in which the second IC die is coupled to at least two of the first IC dies in the plurality of the first IC dies.

Example 17 provides the microelectronic assembly of example 16, further comprising a plurality of the second IC dies, at least some of the plurality of the second IC dies being coupled to at least one of the first IC dies.

Example 18 provides the microelectronic assembly of any one of examples 16-17, in which at least one of the plurality of the second IC dies comprises a metallization stack with conductive traces without any active circuit elements.

Example 19 provides the microelectronic assembly of any one of examples 16-18, in which at least one of the plurality of the second IC dies comprises a memory circuit.

Example 20 provides the microelectronic assembly of any one of examples 1-19, further comprising (e.g., FIG. 2) a third IC die (e.g., 202) embedded in the organic dielectric material, in which the second IC die is coupled to the third IC die by third interconnects (e.g., 204).

Example 21 provides the microelectronic assembly of example 20, in which the second IC die comprises through-substrate vias (TSVs).

Example 22 provides the microelectronic assembly of any one of examples 20-21, in which the TDVs are first TDVs, and the microelectronic assembly further comprises second TDVs (e.g., 206) through the organic dielectric material between the first bond-pads and the third IC die.

Example 23 provides the microelectronic assembly of example 22, in which the second TDVs are coupled to the third IC die by fourth interconnects (e.g., 208).

Example 24 provides the microelectronic assembly of any one of examples 20-23, in which the third IC die is coupled to the package substrate through the second interconnects.

Example 25 provides the microelectronic assembly of any one of examples 20-24, in which the third IC die comprises active circuitry.

Example 26 provides the microelectronic assembly of any one of examples 20-25, in which the third IC die comprises TSVs.

Example 27 provides the microelectronic assembly of any one of examples 1-26, in which (e.g., FIGS. 3, 4): the first bond-pads have a first diameter (e.g., 304), the TDVs have a second diameter (e.g., 306), and the first diameter is smaller than the second diameter.

Example 28 provides the microelectronic assembly of any one of examples 1-26, in which (e.g., FIG. 5): the first bond-pads have a first diameter (e.g., 304), the TDVs have a second diameter (e.g., 306), and the first diameter is larger than the second diameter.

Example 29 provides the microelectronic assembly of any one of examples 1-26, in which (e.g., FIG. 6): the first bond-pads have a first diameter (e.g., 304), the TDVs have a second diameter (e.g., 306), and the first diameter is approximately equal to the second diameter.

Example 30 provides the microelectronic assembly of any one of examples 1-29 (e.g., FIGS. 3, 5, 6) further comprising a polyimide layer (e.g., 302), in which: a first portion of the organic dielectric material is in contact with the first surface, the polyimide layer is in contact with the first portion of the organic dielectric material, and a second portion of the organic dielectric material is in contact with the polyimide layer.

Example 31 provides the microelectronic assembly of any one of examples 1-29 (e.g., FIG. 4) in which the first surface comprises a polyimide layer in direct contact with the organic dielectric material.

Example 32 provides the microelectronic assembly of any one of examples 1-31, in which the organic dielectric material comprises mold compound.

Example 33 provides the microelectronic assembly of any one of examples 1-32, in which the TDVs comprise copper.

Example 34 provides an interposer (e.g., 102), comprising: an organic dielectric material (e.g., 108) having a first surface (e.g., 106) and an opposing second surface (e.g., 112); a first plurality of bond-pads (e.g., 104) on the first surface; a second plurality of bond-pads (e.g., 110) on the second surface; TDVs (e.g., 114) between the first plurality of bond-pads and the second plurality of bond-pads; and one or more IC dies (e.g., 116) in the organic dielectric material, in which: the first surface is in direct contact with another IC die, the TDVs are in direct contact with the first plurality of bond-pads and the second plurality of bond-pads.

Example 35 provides the interposer of example 34, in which the interposer is configured to be coupled to a package substrate through the second plurality of bond-pads.

Example 36 provides the interposer of any one of examples 34-35, in which: the first plurality of bond-pads comprises a first subset of bond-pads having a first pitch and a second subset of bond-pads having a second pitch, and the first pitch is different from the second pitch.

Example 37 provides the interposer of example 36, in which the first pitch is approximately 100 micrometers, and the second pitch is approximately 25 micrometers.

Example 38 provides the interposer of example 36, in which the first pitch is not less than 100 micrometers and the second pitch is not greater than 25 micrometers.

Example 39 provides the interposer of example 36, in which the first pitch is between 25 micrometers and 100 micrometers and the second pitch is not greater than 25 micrometers.

Example 40 provides the interposer of example 36, in which the first pitch is not less than 100 micrometers and the second pitch is between 25 micrometers and 100 micrometers.

Example 41 provides the interposer of any one of examples 36-40, in which the second subset of bond-pads is conductively coupled to the one of more IC dies of the interposer.

Example 42 provides the interposer of any one of examples 34-41, in which at least one IC die in the one or more IC dies is a bridge die configured to laterally couple two other IC dies attached to the first surface of the interposer.

Example 43 provides the interposer of example 42, in which the bridge die does not have any active circuitry.

Example 44 provides the interposer of any one of examples 34-43, in which at least one IC die in the one or more IC dies comprises a memory circuit.

Example 45 provides the interposer of any one of examples 34-44, in which: the one or more IC dies include more than one IC die, the more than one IC dies are arranged in a stack between the first surface and the second surface of the interposer, and each layer of the stack has a plurality of the IC dies.

Example 46 provides the interposer of example 45, further comprising TDVs between the first plurality of bond-pads and the IC dies in the stack.

Example 47 provides a method of fabricating an interposer, the method comprising (e.g., FIGS. 7, 8): providing one or more known good IC dies (KGDs) (e.g., 116) having first bond-pads (e.g., 104); attaching the KGDs to a carrier (e.g., 712); encapsulating the KGDs with an organic dielectric material; forming conductive pillars (e.g., 114) on a first subset (e.g., 104(1)) of the first bond-pads, in which the first bond-pads in the first subset have a first pitch; attaching another KGD (e.g., 116) to a second subset (e.g., 104(2)) of the first bond-pads, in which the first bond-pads in the second subset have a second pitch smaller than the first pitch; encapsulating the conductive pillars and the another KGD with the organic dielectric material; planarizing a surface (e.g., 752) of the organic dielectric material; and forming second bond-pads (e.g., 110) on the planarized surface of the organic dielectric material.

Example 48 provides the method of example 47, further comprising forming additional TDVs over the another KGD before encapsulating with the organic dielectric material, in which the additional TDVs are coupled to corresponding conductive pads on the another KGD.

Example 49 provides the method of any one of examples 47-48, further comprising (e.g., FIG. 7C): before forming conductive pillars, depositing a polyimide layer proximate to the first bond-pads.

Example 50 provides the method of example 49, in which the polyimide layer is deposited to be in contact with surfaces of the KGDs.

Example 51 provides the method of example 49, further comprising (e.g., FIG. 7C): after depositing the polyimide layer, depositing a seed layer (e.g., 722) over the polyimide layer.

Example 52 provides the method of any one of examples 49-51, further comprising (e.g., FIG. 7D): removing the polyimide layer proximate to the second subset of the first bond-pads.

Example 53 provides the method of any one of examples 47-52, further comprising: detaching the carrier (e.g., FIGS. 7G, 8G).

Example 54 provides the method of any one of examples 47-53, in which forming the conductive pillars comprises (e.g., FIG. 8C): depositing a photoresist material (e.g., 822), patterning the photoresist material to form vias (e.g., 824), electroplating the vias with conductive material, and removing the photoresist material.

Example 55 provides the method of any one of examples 47-54, in which attaching another KGD comprises forming interconnects between the another KGD and the second subset of the bond-pads.

Example 56 provides the method of example 55, further comprising: after forming the interconnects, depositing an underfill material (e.g., 120) around the interconnects.

Example 57 provides the method of any one of examples 47-56, further comprising attaching a package substrate to the interposer by forming interconnects between the package substrate and the second bond-pads.

Example 58 provides the method of any one of examples 47-57, further comprising attaching a plurality of the another KGDs to the second subset of the first bond-pads.

Example 59 provides the method of any one of examples 47-58, further comprising repeating forming conductive pillars, attaching another KGD, encapsulating the conductive pillars and the another KGD with the organic dielectric material, and planarizing a surface of the encapsulating organic dielectric material until a desired structure of the interposer is obtained.

Example 60 provides the method of any one of examples 47-59, in which the another KGD is a bridge die without active circuitry.

Example 61 provides the method of any one of examples 47-60, in which the another KGD comprises memory circuitry.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first integrated circuit (IC) die having first bond-pads on a first surface;
an organic dielectric material in contact with the first surface;
second bond-pads on a second surface of the organic dielectric material opposite to the first surface;
through-dielectric vias (TDVs) in the organic dielectric material between the first bond-pads and the second bond-pads, wherein the TDVs are in direct contact with the first bond-pads and the second bond-pads;
a second IC die embedded in the organic dielectric material and coupled to the first bond-pads by first interconnects; and
a package substrate coupled to the second bond-pads by second interconnects.

2. The microelectronic assembly of claim 1, wherein:
the first bond-pads comprise a first subset of bond-pads and a second subset of bond-pads,
the TDVs are in direct contact with the first subset of bond-pads, and
the interconnects between the first IC die and the second IC die are in direct contact with the second subset of bond-pads.

3. The microelectronic assembly of claim 2, wherein:
the bond-pads in the first subset are spaced apart according to a first pitch,
the bond-pads in the second subset are spaced apart according to a second pitch, and
the first pitch is larger than the second pitch.

4. The microelectronic assembly of claim 2, wherein: the bond-pads in the first subset are larger than the bond-pads in the second subset.

5. The microelectronic assembly of claim 1, further comprising an underfill material in the organic dielectric material between the first IC die and the second IC die.

6. The microelectronic assembly of claim 1, further comprising a third IC die embedded in the organic dielectric material, wherein the second IC die is coupled to the third IC die by third interconnects.

7. The microelectronic assembly of claim 1 further comprising a polyimide layer, wherein:
a first portion of the organic dielectric material is in contact with the first surface,
the polyimide layer is in contact with the first portion of the organic dielectric material, and
a second portion of the organic dielectric material is in contact with the polyimide layer.

8. The microelectronic assembly of claim 1 wherein the first surface comprises a polyimide layer in direct contact with the organic dielectric material.

9. An interposer, comprising:
an organic dielectric material having a first surface and an opposing second surface;
a first plurality of bond-pads on the first surface;
a second plurality of bond-pads on the second surface;
TDVs between the first plurality of bond-pads and the second plurality of bond-pads; and
one or more IC dies in the organic dielectric material,
wherein:
the first surface is in direct contact with another IC die,
the TDVs are in direct contact with the first plurality of bond-pads and the second plurality of bond-pads.

10. The interposer of claim 9, wherein the interposer is configured to be coupled to a package substrate through the second plurality of bond-pads.

11. The interposer of claim 9, wherein:
the first plurality of bond-pads comprises a first subset of bond-pads and a second subset of bond-pads,
the first subset of bond-pads has a first pitch,
the second subset of bond-pads has a second pitch, and
the first pitch is different from the second pitch.

12. The interposer of claim 10, wherein the second subset of bond-pads is conductively coupled to the one of more IC dies of the interposer.

13. The interposer of claim 9, wherein at least one IC die in the one or more IC dies is a bridge die configured to laterally couple two other IC dies attached to the first surface of the interposer.

14. The interposer of claim 9, wherein:
the one or more IC dies include more than one IC die,
the more than one IC dies are arranged in a stack between the first surface and the second surface of the interposer, and
one or more IC dies are in each layer of the stack.

15. The interposer of claim 14, further comprising TDVs between the first plurality of bond-pads and the IC dies in the stack.

16. A method of fabricating an interposer, the method comprising:
providing one or more known good IC dies (KGDs) having first bond-pads;
attaching the KGDs to a carrier;
encapsulating the KGDs with an organic dielectric material;
forming conductive pillars on a first subset of the first bond-pads, wherein the first bond-pads in the first subset have a first pitch;
attaching another KGD to a second subset of the first bond-pads, wherein the first bond-pads in the second subset have a second pitch smaller than the first pitch;
encapsulating the conductive pillars and the another KGD with the organic dielectric material;
planarizing a surface of the organic dielectric material; and
forming second bond-pads on the planarized surface of the organic dielectric material.

17. The method of claim 16, further comprising forming additional TDVs over the another KGD before encapsulating with the organic dielectric material, wherein the additional TDVs are coupled to corresponding conductive pads on the another KGD.

18. The method of claim 16, further comprising: before forming conductive pillars, depositing a polyimide layer proximate to the first bond-pads.

19. The method of claim 16, wherein attaching another KGD comprises forming interconnects between the another KGD and the second subset of the bond-pads.

20. The method of claim 19, further comprising: after forming the interconnects, depositing an underfill material around the interconnects.
